(19) United States
(12) Patent Application Publication
(10) Pub. No.: US 2024/0313152 A1
(43) Pub. Date: Sep. 19, 2024

(54) OPTOELECTRONIC DEVICE AND MANUFACTURING METHOD

(71) Applicant: ALEDIA, Echirolles (FR)

(72) Inventors: Ivan-Christophe ROBIN, Grenoble (FR); Zheng Sung CHIO, Melaka (MY)

(21) Appl. No.: 18/575,609

(22) PCT Filed: Jun. 23, 2022
(86) PCT No.: PCT/EP2022/067146

§ 371 Date: Dec. 29, 2023

(30) Foreign Application Priority Data
Jun. 30, 2021 (FR) 2107034

(51) Int. Cl. H01L 33/00; H01L 21/67

(52) U.S. Cl. CPC H01L 33/0093; H01L 21/67144

(57) ABSTRACT

A transfer structure including a substrate and an optoelectronic device attached to the substrate, the substrate including a base portion having a substrate face, and at least one element projecting from the substrate face, the optoelectronic device having a first face including a central zone and a peripheral zone surrounding the central zone, the transfer structure where the at least one projecting element of the substrate is attached to the peripheral zone of the first face of the optoelectronic device. One or more embodiments also relate to a method for transferring optoelectronic devices, which method is based on the implementation of transfer structures.

### TECHNICAL FIELD OF THE INVENTION

The present invention relates to the field of optoelectronic technologies. The invention is particularly advantageous for the manufacture of optoelectronic systems by mass transfer of optoelectronic devices units, for example GaN-based light-emitting diodes.

### PRIOR ART

A self-emissive display screen is an example of a known optoelectronic system. Such a screen comprises a plurality of pixels emitting their own light. Thus, each pixel is typically formed by one or more LED(s), more particularly mini-LEDs or micro-LEDs. Each LED is a unitary optoelectronic device.

To reduce the manufacturing costs of such a screen, and/or to improve the density of LEDs in such a screen, technologies for mass transfer of the LEDs have been developed. Some transfer technologies are based on a so-called “pick and place” principle.

Typically, the unitary devices are individualized on a donor substrate. Afterwards, a handling substrate is attached over a free face of the unitary devices. The donor substrate could then be eliminated, for example by trimming. Afterwards, the unitary devices are detached from the handling substrate and transferred onto a receiver substrate.

To easily attach and detach the unitary devices with respect to the handling substrate, a solution disclosed by document U.S. Pat. No. 9,379,092 B2 consists in forming a sacrificial structure partially wrapping each device, during the manufacture of the devices. According to this method, after transfer of the devices wrapped by the sacrificial structures onto the handling substrate, the donor substrate is removed by trimming. The sacrificial structures and the holding pads allow holding and stabilizing the devices during trimming. Afterwards, the etching of the sacrificial structures allows partially clearing the devices. Thus, the devices are retained only by the small-sized holding pads. The devices are then assembled on a receiver substrate and detached from the handling substrate. Detachment is facilitated by the use of the holding pads.

A drawback of this solution is that the manufacture of the device should be adapted in particular to provide for and form the sacrificial structure. This makes the method complex and restrictive. This limits the versatility of the transfer method. Moreover, a sufficient space should be provided for between the unitary devices to enable etching of the sacrificial structures. This limits the possibilities for densifying the unitary devices and therefore reducing costs. The holding pads might leave residues on the devices upon detachment. It is then more difficult to obtain a good electrical contact on the devices.

The present invention aims to at least partially overcome the aforementioned drawbacks. In particular, an object of the present invention is to provide a transfer structure allowing transferring an optoelectronic device in an optimized manner. Another object of the present invention is to provide a method for transferring optoelectronic devices.

The other objects, features and advantages of the present invention will be clear after an examination of the following description and the accompanying drawings. It is understood that other advantages could be incorporated. In particular, some features and some advantages of the transfer method may be applied mutatis mutandis to the structure or to the transfer system, and vice versa.

### SUMMARY OF THE INVENTION

To achieve the aforementioned objectives, one aspect relates to a transfer structure comprising a support and an optoelectronic device attached to the support, the support comprising a base portion having a support face, and at least one element projecting from the support face, the optoelectronic device having a first face comprising a central area and a peripheral area surrounding the central area.

Advantageously, the at least one projecting element of the support is attached to the peripheral area of the first face of the optoelectronic device, so that the support face, the at least one projecting element and the first face of the device form a cavity under the central area. Thus, the at least one projecting element lies under the optoelectronic device and at the boundary thereof. The at least one projecting element is formed as one or more vertical cantilever(s) supporting the peripheral area of the optoelectronic device. The lateral bulk of the transfer structure is reduced. This allows increasing the density of optoelectronic devices over the support. Thus, a cavity delimited by the vertical cantilevers is formed under the central area of the device.

This allows easily detaching the optoelectronic device from its support, for example by exerting a vertical force on the optoelectronic device.

The central area of the device is also preserved. It may be functionalized, for example by carrying metal contacts of the optoelectronic device.

Another aspect relates to a transfer system comprising a plurality of adjacent transfer structures.

Advantageously, at least one projecting element of two adjacent transfer structures is common to the peripheral areas of said adjacent transfer structures. This allows increasing the density of transfer structures within said transfer system.

Another aspect relates to a method for transferring a plurality of optoelectronic devices from a first substrate to a second substrate, said method comprising at least the following steps:
providing the first substrate carrying the optoelectronic devices, each of said optoelectronic devices having a first face on a side opposite to the first substrate, said first face comprising a central area and a peripheral area surrounding the central area,
forming a support for the optoelectronic devices, said support comprising a base portion having a support face, and at least one element projecting from the support face, each peripheral area being attached to said at least one projecting element, so that the support face, the at least one projecting element and the first face of the device form a cavity under the central area,
removing the first substrate,
detaching the optoelectronic devices from the support, and transferring them onto a second substrate, at their first faces.

Thus, the method advantageously allows transferring a plurality of optoelectronic devices via the support.

The optoelectronic devices may comprise at least one light-emitting diode, typically formed over the first substrate, and preferably an electrical interconnection portion hybridized over the diode.

This electrical interconnection portion may be formed separately over a support layer, then affixed by hybridization on the diode, before forming the support. The electrical interconnection portion may also comprise an electronic control circuit dedicated to control of the diode, to form “smart” LEDs.

The support may be made independently of the devices. This allows reducing constraints on the design of the devices.

Alternatively, the at least one projecting element of the support may be formed from the device, for example by taking advantage of the support layer of the electrical interconnection portion. Advantageously, this method may be applied during transfer of LEDs or smart LEDs from a donor substrate, for example a growth substrate, to a receiver substrate, for example a CMOS substrate comprising a control circuitry the LEDs.

### BRIEF DESCRIPTION OF THE FIGURES

The aims, objects, as well as the features and advantages of the invention will appear better from the detailed description of embodiments of the latter which are illustrated by the following accompanying drawings, wherein:

FIGS. 1A to 1M illustrate steps of a method for transferring LEDs according to a first embodiment of the present invention.

FIGS. 2A to 2M illustrate steps of a method for transferring LEDs according to a second embodiment of the present invention.

FIGS. 3A to 31 illustrate steps of a method for transferring LEDs according to a third embodiment of the present invention.

The drawings are given as examples and are not limiting to the invention. They are schematic representations of a principle intended to facilitate the understanding of the invention and are not necessarily on the scale of the practical applications. In particular, the dimensions of the different portions of the transfer structures and of the LEDs do not necessarily represent reality.

### DETAILED DESCRIPTION

Before starting a detailed review of embodiments of the invention, it should be recalled that the invention comprises in particular the optional features hereinafter which could be used in combination or alternatively.

According to one example, the transfer structure comprises at least two projecting elements, and preferably at least four projecting elements, evenly arranged on either side of the central area. This allows balancing the mechanical forces applied to the support or to the structure. Preferably, the projecting elements are arranged according to a central symmetry with respect to the center or the barycenter of the central area, in projection on a base plane parallel to the face of the support.

According to one example, the central area of the first face comprises at least one metal contact. Advantageously, this metal contact is not covered or is not partially covered by a projecting element. Thus, it is directly functional, without the need for a prior step of cleaning or removing the element(s) covering it.

According to one example, the at least one projecting element has a first dimension according to a first direction x, a second dimension according to a second direction y, and a third dimension according to a third direction z, the first and second directions x, y forming a base plane parallel to the support face, and the third direction z being perpendicular to this base plane. Said first, second and third dimensions are such that at least one amongst the first and second dimensions is smaller than the third dimension. Thus, the at least one projecting element extends essentially vertically, for example according to z or in a plane zx or in a plane zy. Thus, its horizontal extension, in a xy plane, remains limited.

According to one example, the optoelectronic device comprises at least one light-emitting diode in line with the central area, and has a second face opposite to the first face, said second face forming a light emission face. Preferably, the at least one light-emitting diode is circumscribed by the peripheral area, in projection on a base plane parallel to the face of the support. In this case, the at least one light-emitting diode occupies only the central area. It does not extend over the peripheral area.

According to one example, the optoelectronic device further comprises an electrical interconnection portion forming the first face. This electrical interconnection portion may comprise vias and/or one or more electronic control circuit(s), also called μIC. The optoelectronic device comprising at least one light-emitting diode and an electronic control microcircuit associated with said at least one diode typically forms a “smart LED”.

According to one example, the adjacent optoelectronic devices are separated from one another by trenches formed directly above the at least one projecting element. Thus, the optoelectronic devices are “individualized”. The trenches may completely or partially separate the optoelectronic devices from one another. In particular, the trenches may extend, according to a direction perpendicular to the face of the support, under a reference plane comprising the first faces of the devices. Alternatively, the bottom of the trenches may be located above said reference plane. According to one example, the at least one projecting element has a first dimension according to a first direction x and a second dimension according to a second direction y, the first and second directions x, y forming a base plane parallel to the support face, and the trenches have at least one dimension according to at least one amongst the first and second directions x, y is smaller than the first and second dimensions of the at least one projecting element. Thus, the trenches are narrower than the at least one projecting element. In projection on a base plane parallel to the face of the support, the width of the trenches is smaller than the width of the at least one projecting element, said widths being considered according to a same direction of the base plane. According to one example, the trenches extend into the at least one projecting element according to a third direction z perpendicular to the first and second directions x, y. The bottom of the trenches is then located under the reference plane comprising the first faces of the devices.

According to one example, the method further comprises, after removing the first substrate and before detaching the optoelectronic devices, forming trenches separating the optoelectronic devices from one another, so that these are individualized and supported only by the at least one projecting element.

According to one example, the trenches are formed by etching directly above the at least one projecting element, starting from a second face of the optoelectronic devices opposite to the first face.

According to one example, etching is configured so that the trenches run partially in the at least one projecting element.

According to one example, each of the optoelectronic devices comprises at least one light-emitting diode and an electrical interconnection portion, the at least one light-emitting diode being made on the first substrate and said electrical interconnection portion being made separately on a support layer, said electrical interconnection portion then being transferred by hybridization onto the at least one light-emitting diode, before forming the support.

According to one example, the at least one projecting element is formed before being attached to the peripheral areas of the first faces of the optoelectronic devices. Typically, the at least one projecting element is formed by etching a silicon substrate. The bulk portion of the silicon substrate then forms the base portion of the support. Thus, the support is formed aside the optoelectronic device.

According to an alternative example, the at least one projecting element is formed by etching the support layer, and is then affixed onto a planar substrate so as to form the support, before removing the first substrate. Thus, the at least one projecting element is formed from the microelectronic device. Thus, the support is formed after the at least one projecting element is attached to the peripheral areas of the first faces of the optoelectronic devices.

According to one example, the method further comprises, before detaching the optoelectronic devices, fastening only part of said optoelectronic devices on the support face, said fastening being carried out by depositing an adhesive material in the cavity, between the central area and the support face. This allows retaining some devices on the support, during transfer of the other devices to the second substrate, so-called the receiver substrate.

According to one example, the method further comprises, before fastening, an electrical test configured to detect defective optoelectronic devices, said fastening being carried out only for said defective optoelectronic devices. This allows retaining the defective devices on the support, during the transfer of the other devices to the receiver substrate.

Unless incompatible, technical features described in detail for a given embodiment may be combined with the technical features described in the context of other embodiments described for exemplary and non-limiting purposes, so as to form another embodiment which is not necessarily illustrated or described. Of course, such an embodiment is not excluded from the invention.

In the present invention, the method is dedicated in particular to the transfer of light-emitting diodes (LEDs), and in particular smart LEDs.

The invention may be implemented more generally for different optoelectronic devices, and possibly for microelectromechanical systems MEMS. Hence, the invention may be implemented in the context of laser or photovoltaic devices.

In the context of the present invention, the transfer structure and the transfer method are dedicated to the transfer of “elementary” devices whose dimensions do not exceed a few tens or hundred microns. These elementary devices or components are generally manufactured by microelectronics technologies, then cut and/or assembled. In the case of microelectronic devices, these may be encapsulated in a protective package, for example based on an epoxy resin. Such an epoxy package typically contains a plurality of elementary components and cannot be assimilated to an elementary or unitary device in the sense of the present invention. Thus, the transfer structure and the transfer method according to the present invention are not applicable to the transfer of such packages whose dimensions generally larger than several millimeters are in no way comparable with the optoelectronic devices targeted by the present invention. The packaging and handling of the packages belong to the “packaging” field, whereas the present invention is typically implemented before considering any packaging step. A person skilled in the art of packaging is not a person skilled in the art to which the present invention relates. The fields of packaging and of the present invention are perfectly distinct and do not implement the same technologies.

Unless explicitly stated otherwise, it is specified that, in the context of the present invention, the relative arrangement of a third layer interposed between a first layer and a second layer, does not necessarily mean that the layers are directly in contact with one another, but means that the third layer is either directly in contact with the first and second layers, or separated from these by at least one other layer or at least one other element.

Thus, the terms and locutions “bear” and “cover” do not necessarily mean “in contact with”. The steps of the method as claimed should be understood in the broad sense and could possibly be carried out in several sub-steps.

In the present patent application, the terms “light-emitting diode”, “LED” or simply “diode” are interchangeably used. An “LED” could also be understood as a “mini-LED” or “micro-LED” or a smart LED, where appropriate.

In the present invention, “surround” does not necessarily mean “surround with a closed contour”. In particular, the at least one projecting element may form a discontinuous contour around the central area, in projection in a base plane parallel to the face of the support. The attachment points of the at least one projecting element on the peripheral area may form a discontinuous contour. The portions of the optoelectronic device cooperating with the at least one projecting element are not necessarily continuous.

Thus, the cavity may be partially open.

By “evenly arranged” or “an even arrangement”, it should be understood a periodic arrangement of the projecting elements, for example so that adjacent projecting elements are spaced apart from one another by a substantially constant distance.

By a substrate, a layer, a device, “based on” a material M, it should be understood a substrate, a layer, a device comprising only this material M or this material M and possibly other materials, for example alloying elements, impurities or doping elements. Thus, a GaN-based diode typically comprises GaN and AlGaN or InGaN alloys.

A reference frame, preferably orthonormal, comprising the axes x, y, z is shown in the appended figures.

In the present patent application, we will talk about a thickness for a layer and about a height for a structure or a device. The thickness is considered according to a direction normal to the main extension plane of the layer, and the height is considered perpendicularly to the base plane xy. Thus, a layer typically has a thickness according to z, when it extends mainly along a plane xy, and a projecting element has a height according to z. Preferably, the relative terms “over”, “under”, “underlying” refer to positions considered according to the direction z. The projecting elements may be in the form of pillars extending according to z, or with walls extending according to a plane xz or yz. When the projecting elements are in the form of walls extending according to xz, they typically have a width dimension according to y. When the projecting elements are in the form of walls extending according to yz, they typically have a width dimension according to x. The width dimension of the projecting elements may vary along the height of the projecting elements. In this case, the width may correspond to an average value of the width over the entire height. The trenches typically extend according to planes xz or yz and typically have a width dimension according to y or according to x, respectively. In the case of trenches too, the width may correspond to an average value of the width over the entire height.

The dimensional values should be understood considering the manufacturing and measurement tolerances.

The terms “substantially”, “about”, “in the range of” mean, when they relate to a value, “within a 10% margin” to this value or, when they relate to an angular orientation, “within a 10° margin” to this orientation. Thus, a direction substantially normal to a plane means a direction having an angle of 90+10° with respect to the plane.

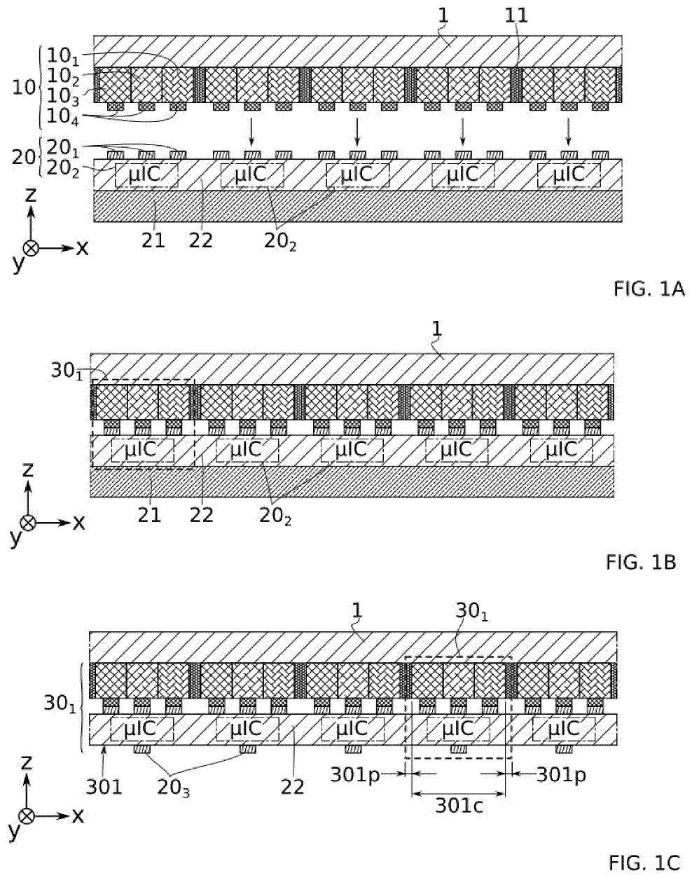

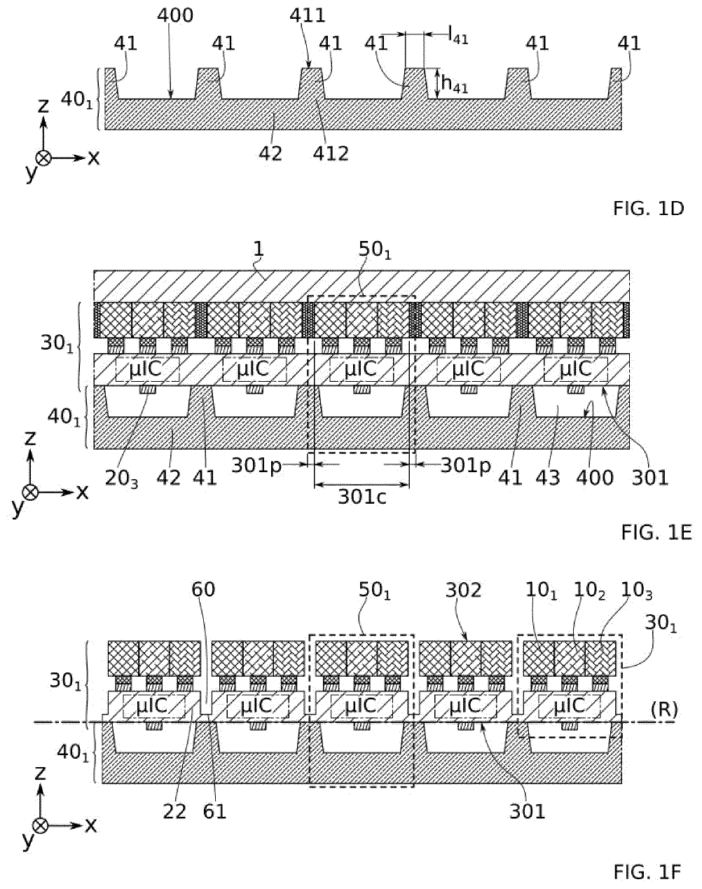

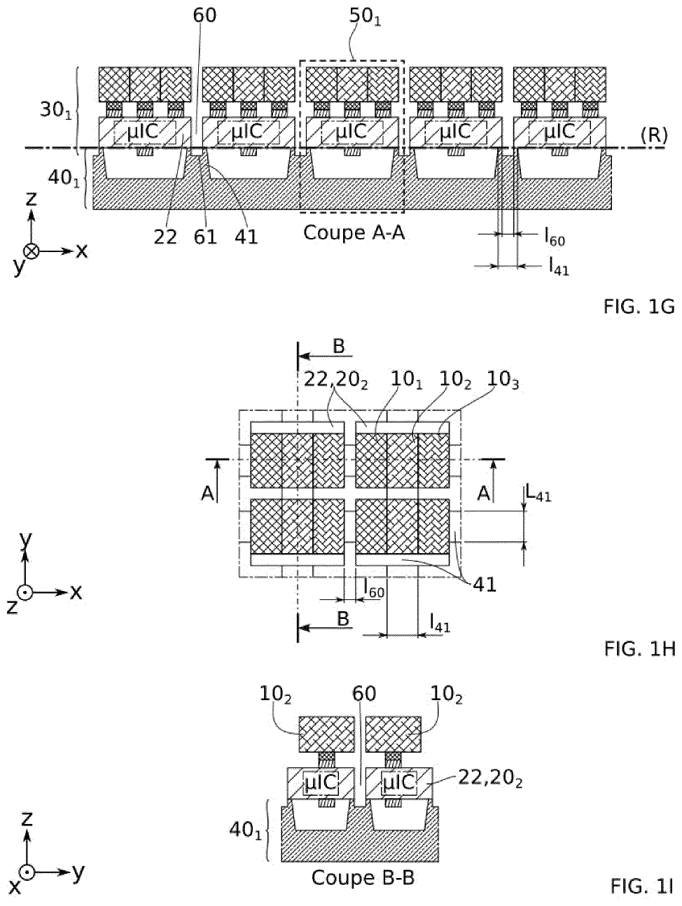

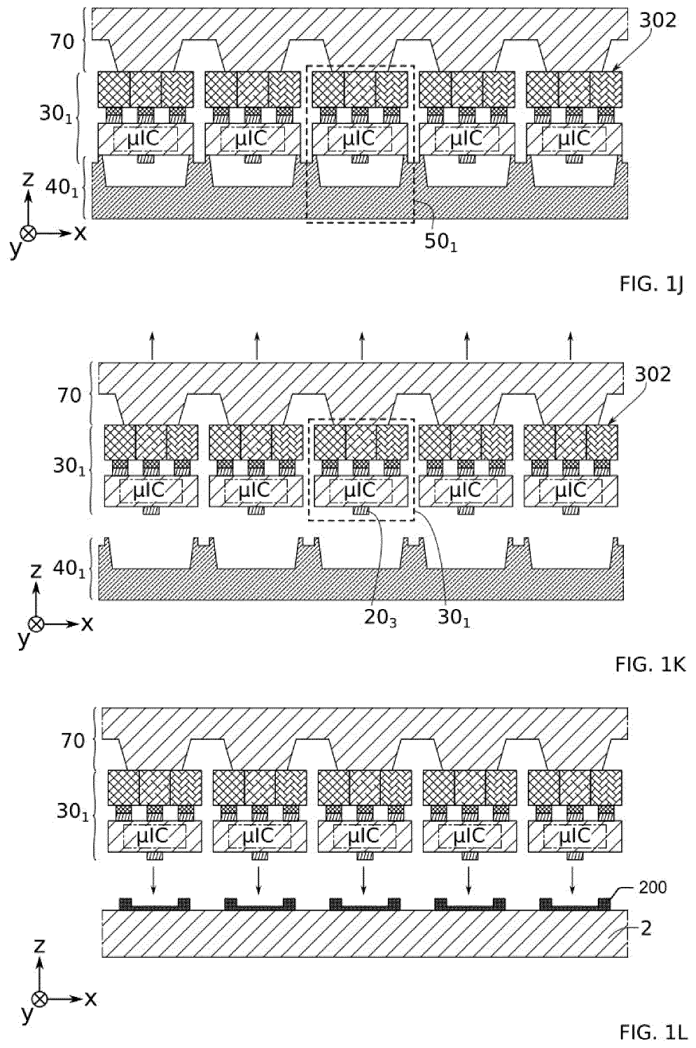

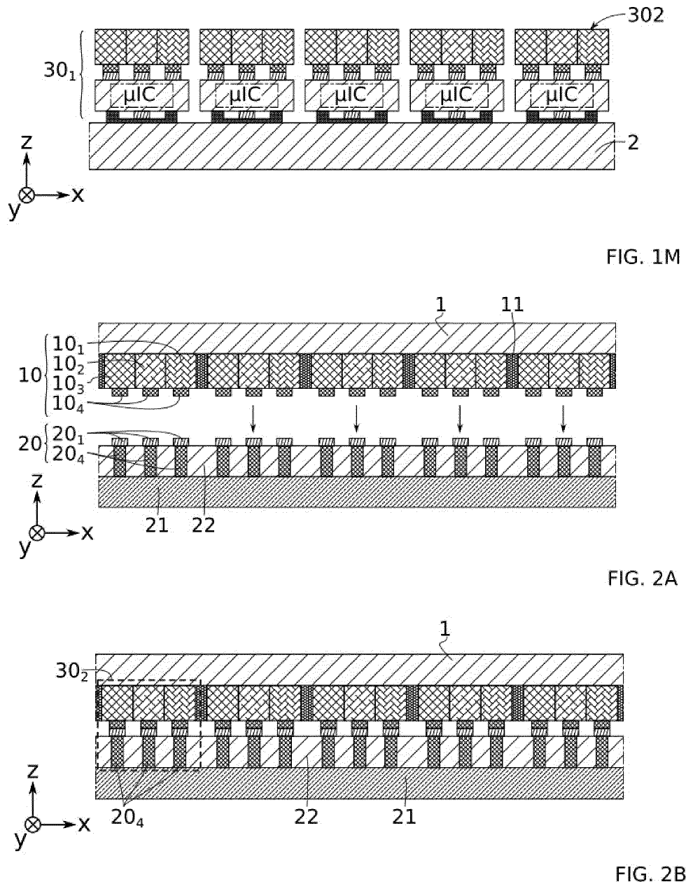

A first embodiment of the method according to the invention is illustrated in FIGS. 1A to 1M. This first embodiment aims to transfer smart LEDs from a growth substrate 1 onto a receiver substrate 2. The smart LEDs typically comprise an emissive portion 10 based on LED or μLED and an electrical interconnection portion 20. In particular, this electrical interconnection portion 20 may comprise control electronics based on integrated microcircuits μIC.

As illustrated in FIG. 1A, a first step of this method consists in providing a growth substrate 1 carrying LEDs 10₁, 10₂, 10₃. These LEDs 10₁, 10₂, 10₃ may typically comprise so-called RGB (acronym for Red Green Blue) LEDs, for example a red LED 10₁, a green LED 10₂, a blue LED 10₃. According to another possibility, the growth substrate 1 carries only monochromatic LEDS. The growth substrate 1 may typically be based on III-V materials. In a known manner, such a substrate 1 may comprise a base made of silicon or sapphire over which buffer and/or nucleation layers based on III-V materials are epitaxed (not illustrated). The LEDs 10₁, 10₂, 10₃ are grown starting from the layers based on III-V materials.

The LEDs 10₁, 10₂, 10₃ may be encapsulated in an encapsulation material 11. Metal contacts 10₄ are typically formed on each of the LEDs 10₁, 10₂, 10₃.

Afterwards, these LEDs 10₁, 10₂, 10₃ may be transferred onto an electrical interconnection portion carried by a support layer 21. In this example, the electrical interconnection portion 20 consist of control circuitry. The control circuitry 20 is typically formed in a semiconductor layer 22 comprising integrated circuits 20₂. Contact pads 20₁ are typically arranged on each of the integrated microcircuits 20₂. The contact pads 20₁ and the metal contacts 10₄ are aligned opposite one another, then assembled with one another.

As illustrated in FIG. 1B, the growth substrate 1 carrying the LEDs may be assembled to the support layer 21 carrying the μIC 20₂, by hybridization between the metal contacts 10₄ and the contact pads 20₁. At this stage, a plurality of smart LEDs 30₁ is formed. These smart LEDs 30₁ are interposed between the growth substrate 1 and the support layer 21.

As illustrated in FIG. 1C, the support layer 21 is first removed, for example by trimming or by thinning, so as to expose a first face 30₁ of the smart LEDs 30₁. Metal contact pads 20₃ may be formed on this face 30₁ at the μICs 20₂. The number and the position of the contact pads 20₃ may vary according to the architecture of the μICs 20₂. For each of the smart LEDs 30₁, a central area 30₁c and a peripheral area 30₁p of the first face 30₁ may be defined. Preferably, the central area 30₁c is substantially directly above the μIC and/or the LEDs 10₁, 10₂, 10₃ according to z. Thus, the contact pads 20₃ are preferably located within the central area 30₁c. Preferably, he peripheral area 30₁p is located substantially directly above the encapsulation material surrounding the LEDs 10₁, 10₂, 10₃. The peripheral area 30₁p surrounds the central area 30₁c.

As illustrated in FIG. 1D, a support 40₁ comprising a base portion 42 and projecting elements 41 is provided. This support 40₁ may be formed from a bulk substrate, for example a silicon substrate. Preferably, the projecting elements 41 are formed by etching the bulk substrate. Thus, these projecting elements 41 may have different shapes or patterns. For example, they may be in the form of pillars or walls separated from one another. Alternatively, the projecting elements 41 may form a continuous network, for example a grid with square or rectangular meshes, when viewed from above according to z. The projecting elements 41 have a width I₄₁ or L₄₁ and a height h₄₁. The width I₄₁ is typically less than the height h₄₁. The projecting elements 41 may have a trapezoidal or frustoconical shape, as illustrated in FIG. 1D. Thus, the top 411 of the projecting elements 41 may be slightly less wide than the base 412 of the projecting elements 41. This may be due to the etching parameters allowing obtaining the support 40₁. The width I₄₁ may be comprised between 500 nm and 100 microns. The height h₄₁ may be comprised between 500 nm and 1 mm.

As illustrated in FIG. 1E, the support 40₁ is assembled to the smart LEDs 30₁ carried by the growth substrate 1. The projecting elements 41 are aligned with the peripheral areas 30₁p of each of the smart LEDs 30₁. Preferably, at least two projecting elements 41 are assembled on two opposite sides of a peripheral area 30₁p. Preferably, at least four projecting elements 41 are assembled on four opposite sides of a peripheral area 30₁p. Thus, the projecting elements 41 may be evenly distributed along a considered peripheral area 30₁p, in projection according to z. This allows improving the mechanical stability of the assembly.

Thus, transfer structures 501 are formed. Each of these transfer structures 501 comprises an electronic device, in this case a smart LED 30₁, and at least partially the support 40₁. Thus, a cavity 43 is formed in each transfer structure 501. This cavity 43 is bordered by the projecting elements 41, the support face 400 and the first face 30₁. The cavity 43 typically allows accommodating metal contacts 20₃. Thus, these are protected without being covered by a protective layer or another element. This allows avoiding a subsequent step of cleaning these metal contacts 20₃.

The transfer structures 501 have enough mechanical strength to remove the growth substrate 1. As illustrated in FIG. 1F, the growth substrate 1 is then removed, for example by trimming. Thus, a face 30₂ of the smart LEDs is exposed. This face 30₂ typically allows emitting the light.

Trenches 60 are formed between each of the smart LEDs, so as to individualize the smart LEDs with respect to one another. These trenches 60 may be formed by etching starting from the face 30₂. The trenches 60 are made substantially in line with the peripheral areas of each transfer structure 501, in particular in line with the projecting elements 41. They typically pass through the encapsulation material delimiting each group of LEDs 10₁, 10₂, 10₃ of the smart LEDs 30₁. The trenches 60 illustrated in FIG. 1F extend mainly according to a plane yz. They are deep enough to isolate the LED-based portions 10₁, 10₂, 10₃ of the smart LEDs from one another. The bottom 61 of the trenches 60 may be located in the semiconductor layer 22, above a reference plane R comprising the first face 30₁, as illustrated in FIG. 1F.

According to another example illustrated in FIG. 1G, the bottom 61 of the trenches 60 may be located under the reference plane R. In this case, the width 60 of the trenches 60 is smaller than the width I₄₁ of the projecting elements 41. Thus, the trenches 60 extend according to z in the projecting elements 41.

Thus, the smart LEDs are partially or totally separated from one another and connected to the projecting elements 41. FIG. 1H has a plurality of smart LEDs separated from one another, in top view. The semiconductor layer 22 may form a perimeter to the LEDs 10₁, 10₂, 10₃, in projection in the plane xy. In the example illustrated in FIG. 1H, four projecting elements 41 are illustrated for each of the smart LEDs. These projecting elements 41 are distributed symmetrically on each of the four sides of a smart LED. Preferably, a given projecting element 41 is shared by two adjacent smart LEDs. According to a non-illustrated possibility, the projecting elements 41 may be located at the corners of the smart LEDs. In this case, a projecting element 41 is shared by four adjacent smart LEDs.

FIG. 1I is a sectional view according to the plane B-B shown in FIG. 1H. Trenches 60 extending mainly according to a plane xz are also formed to separate the smart LEDs from one another.

As illustrated in FIG. 1J, a transfer device 70, for example an elastomer pad, is brought into contact with the faces 30₂ of the smart LEDs. This transfer device 70 typically bears vertically on the faces 30₂.

As illustrated in FIG. 1K, the transfer device 70 is then removed while keeping the smart LEDs 30₁. The force exerted by the transfer device 70 allows detaching the support 40₁ from the smart LEDs 30₁. The small bearing surface between the projecting elements 41 and the smart LEDs 30₁ facilitates the detachment of the support 40₁. Preferably, the bonding force between the transfer device 70 and the face 30₂ of a smart LED is greater than the retaining force between the projecting elements 41 and said smart LED 30₁. The transfer device 70 may also exert a mechanical force directed towards the support and/or parallel to the support so as to break the projecting elements 41 by pressure and/or shearing.

As illustrated in FIGS. 1L and 1M, the smart LEDs 30₁ are then brought by the transfer device 70 opposite the receiver substrate 2. The smart LEDs 30₁ are then assembled to the receiver substrate 2, then the transfer device 70 is removed. This first embodiment of the invention allows efficiently transferring smart LEDs 30₁ from a growth substrate 1 to a receiver substrate 2.

According to one possibility, the smart LEDs 30₁ are considered one-by-one by the transfer device 70. According to one possibility, the transfer device 70 allows modifying a spacing or a separation distance between the smart LEDs 30₁ during transfer, after detachment of the support 40₁ and before transfer onto the receiver substrate 2. Thus, the surface density of the smart LEDs 30₁ may vary between the support 40₁ and the receiver substrate 2. The receiver substrate 2 may comprise structures 200 for accommodating the smart LEDs 30₁, such as contact pads. According to one possibility, the receiver substrate 2 may be a screen substrate comprising electrical tracks and associated contact pads.

Other embodiments of the invention may be considered. Next, only the distinctive features of the other embodiments with regards to the first embodiment are described. The non-described other features are deemed to be identical to those of the first embodiment.

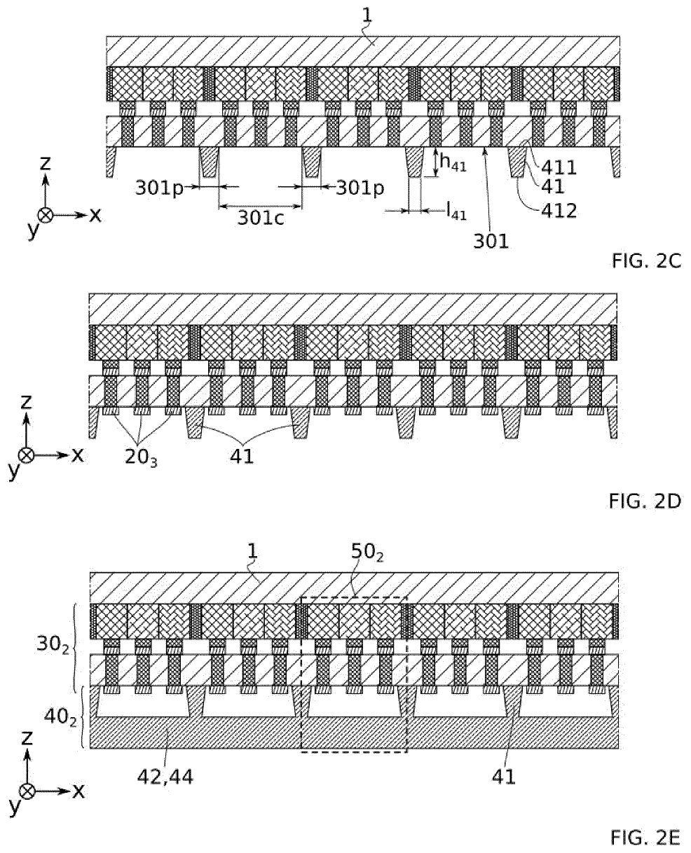

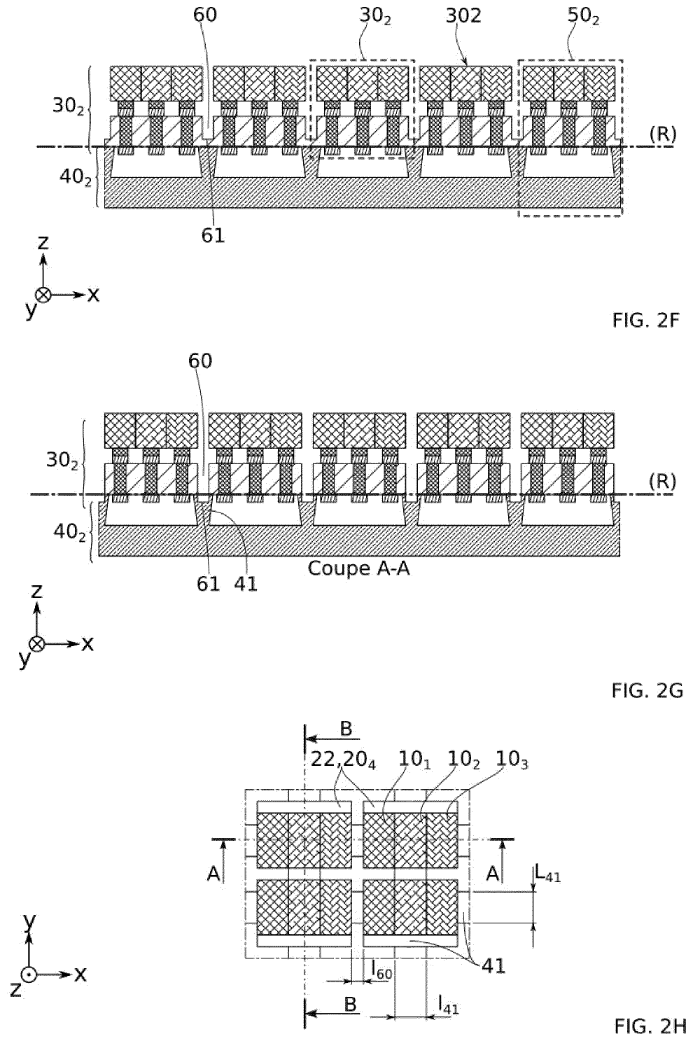

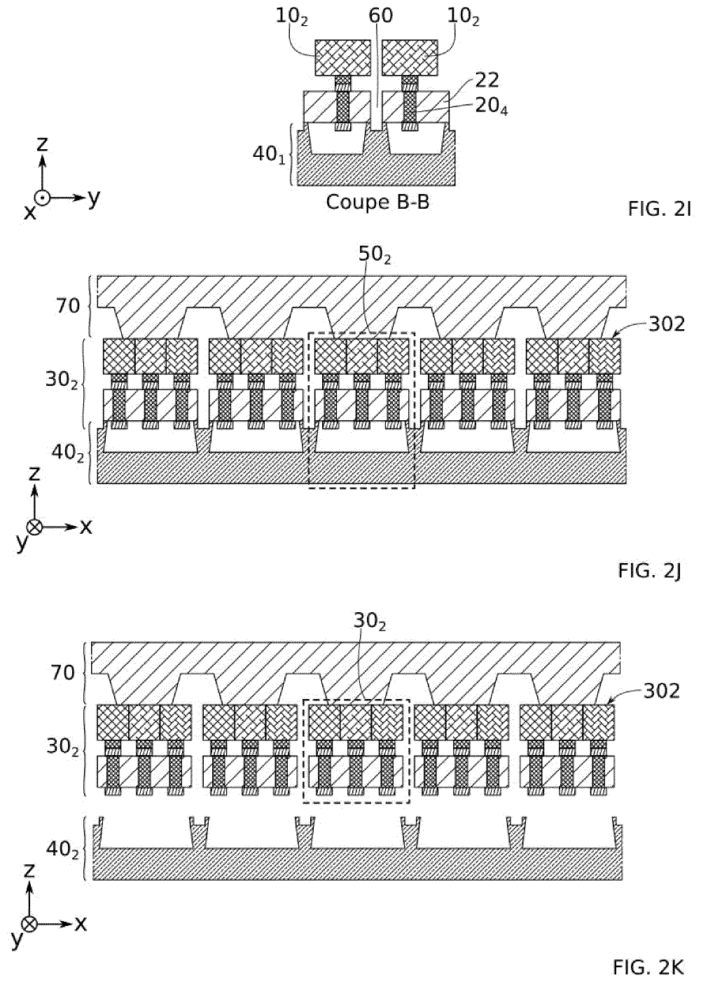

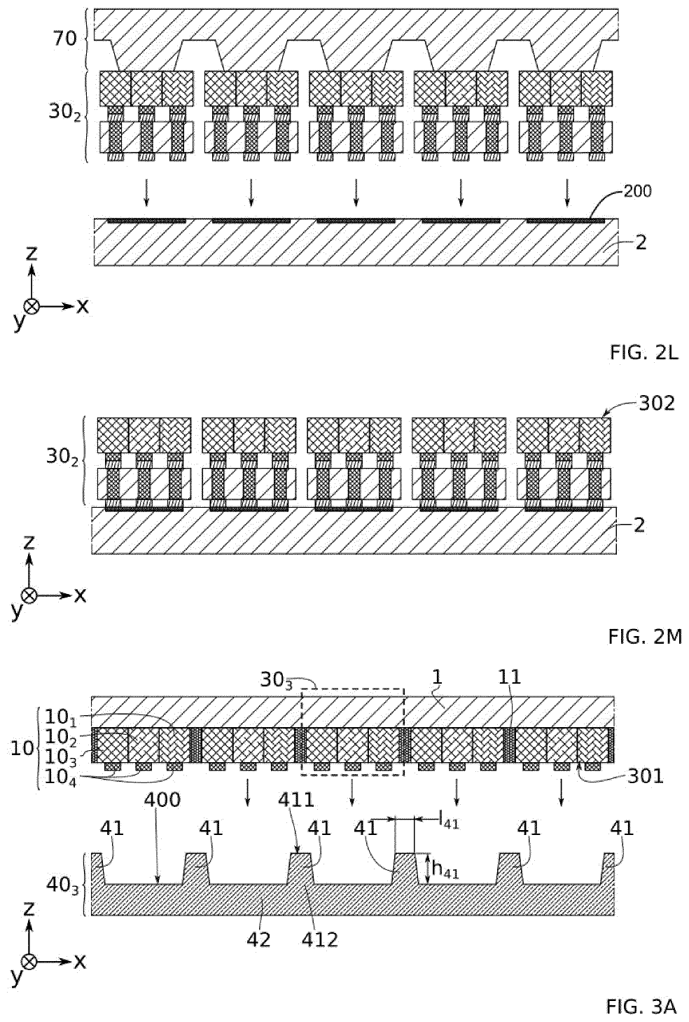

FIGS. 2A to 2M illustrate a second embodiment allowing transferring optoelectronic devices from a growth substrate to a receiver substrate.

As illustrated in FIG. 2A, a growth substrate 1 carrying LEDs 10₁, 10₂, 10₃ and contacts 10₄ is provided like before. In this example, the electrical interconnection portion 20 comprises vias 20₄. These vias are more commonly called TSVs (acronym for “Through Silicon Vias”). The vias or

TSVs are typically electrically conductive. These vias 20₄ cross the semiconductor layer 22. The vias 20₄ are typically associated with contact pads 20₁. The electrical interconnection portion 20 could possibly comprise other elements such as the previously-described μIC. The electrical interconnection portion 20 is carried by the support layer 21, like before.

As illustrated in FIG. 2B, after alignment, the LEDs 10₁, 10₂, 10₃ are assembled with the electrical interconnections, by hybridization between the respective contact pads 10₄, 20₁. At this stage, a plurality of devices 30₂ is formed. These devices 30₂ are interposed between the growth substrate 1 and the support layer 21. Each device 30₂ comprises a group of LEDs 10₁, 10₂, 10₃ and an electrical interconnection portion.

In this embodiment, as illustrated in FIG. 2C, the projecting elements 41 are formed starting from the support layer 21. In this example, an etching of the support layer 21 configured to stop on the semiconductor layer 22 typically allows forming the projecting elements 41 at the peripheral areas 30₁p. Henceforth, the projecting elements 41 may have a trapezoidal or frustoconical shape, as illustrated in FIG. 2C. Unlike the first embodiment, the top 411 of the projecting elements 41 is herein wider than the base 412 of the projecting elements 41.

As illustrated in FIG. 2D, contact pads 20₃ may be formed on the first faces 30₁ of the devices at vias 20₄, between the projecting elements 41.

As illustrated in FIG. 2E, a planar substrate 44 is then assembled to the projecting elements 41 so as to form the base portion 42 of the support 40₂. In this embodiment, the base portion 42 and the projecting elements 41 are therefore formed separately, then assembled. Thus, a transfer structure 50₂ is obtained.

Like before and as illustrated in FIGS. 2F and 2G, the growth substrate 1 is then removed and trenches 60 are formed so as to individualize the devices 30₂ with respect to one another. The bottom 61 of the trenches 60 may be located above the reference plane R (FIG. 2F), or below the reference plane R (FIG. 2G).

FIG. 2H shows the devices viewed from above, each being supported by four projecting elements 41. FIG. 2I shows the devices according to the sectional plane B-B illustrated in FIG. 2H.

Like before and as illustrated in FIGS. 2J to 2M, a transfer device 70 is assembled to the faces 30₂ of the devices (FIG. 2J). Afterwards, the transfer device 70 exerts a vertical tension according to z so as to detach the devices 30₂ from the support 40₂ (FIG. 2K). The devices 30₂ are then brought by the transfer device 70 opposite a receiver substrate 2 (FIG. 2L). The devices 30₂ are assembled to the receiver substrate 2 and then the transfer device 70 is removed (FIG. 2M).

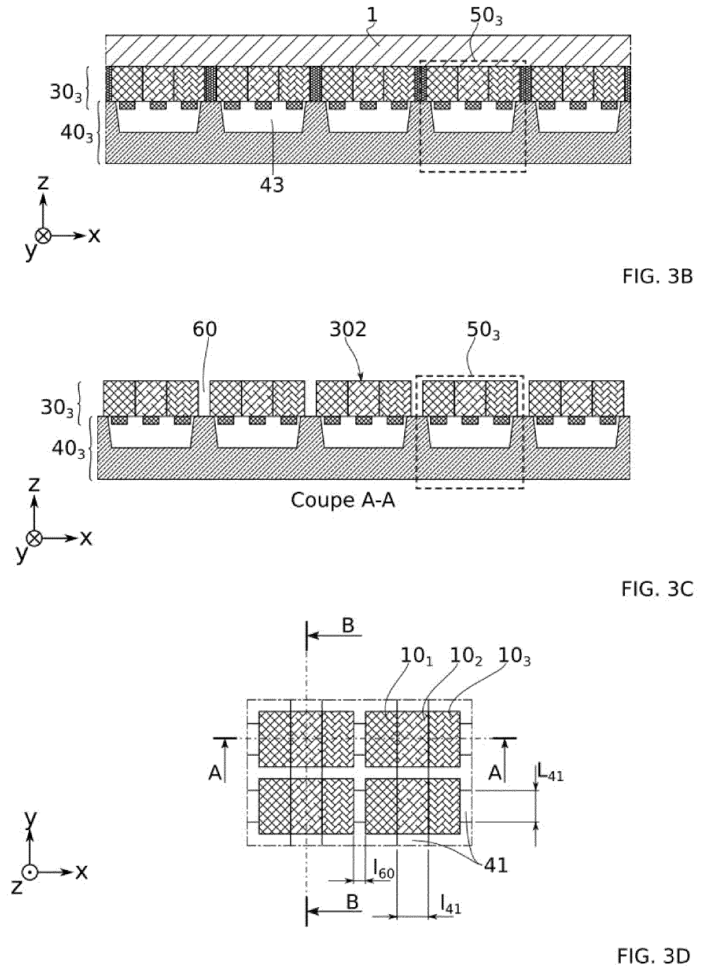

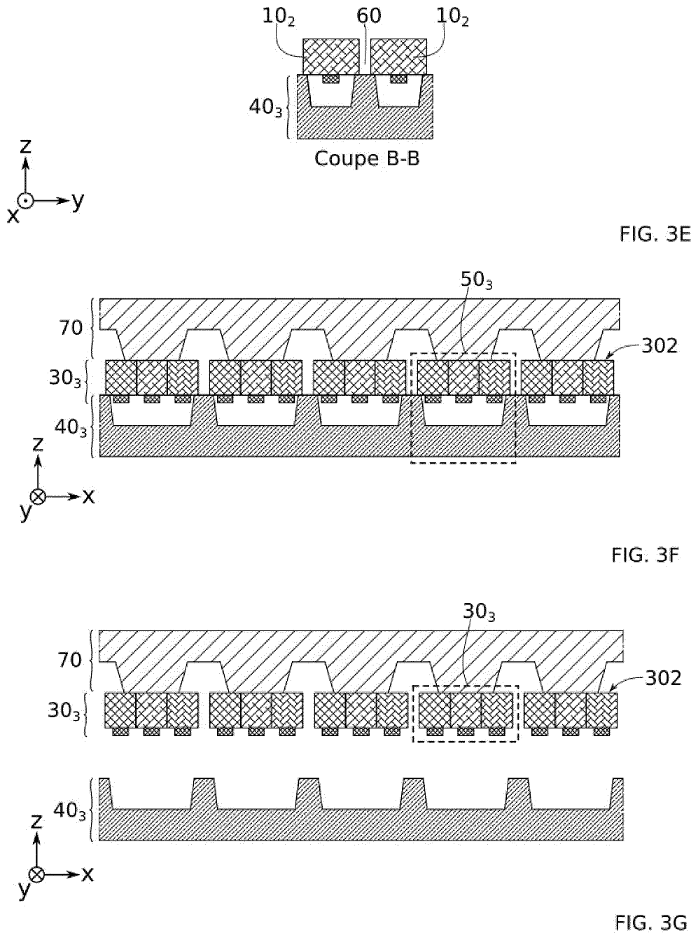

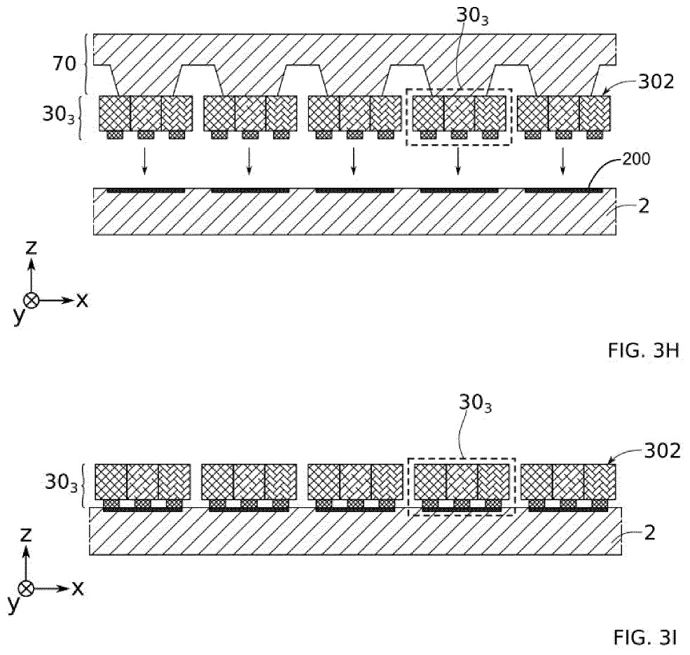

A third embodiment of the invention is illustrated in FIGS. 3A to 31. In this embodiment, the devices 30₃ are RGB pixels comprising three LEDs 10₁, 10₂, 10₃.

According to this embodiment, the LEDs 10₁, 10₂, 10₃ carried by the growth substrate 1 are directly assembled to the support 40₃, without any intermediate hybridization step (FIG. 3A). Thus, a transfer structure 50₃ comprising the pixel 30₃ and at least partially the support 40₃ is formed (FIG. 3B).

Like before and as illustrated in FIG. 3C, the growth substrate 1 is then removed and trenches 60 are formed so as to individualize the pixels 30₃ with respect to one another.

FIG. 3D shows the pixels viewed from above, each being supported by four projecting elements 41. FIG. 3E shows the pixels according to the sectional plane B-B illustrated in FIG. 3D. Only the sub-pixels formed by the green LEDs 10₂ are herein visible.

Like before and as illustrated in FIGS. 3F to 31, a transfer device 70 is assembled to the faces 30₂ of the pixels (FIG. 3F). Afterwards, the transfer device 70 removes the pixels 30₃ from the support 40₃ (FIG. 3G). The pixels 30₃ are then brought by the transfer device 70 opposite a receiver substrate 2 (FIG. 3H). The pixels 30₃ are assembled to the receiver substrate 2 and then the transfer device 70 is removed (FIG. 3I).

According to one embodiment, prior to the transfer of the LEDs (or smart LEDs), an electrical test of all LEDs is performed so as to detect the defective LEDs. According to one possibility, when an LED is considered to be defective upon completion of the test, an adhesive material, for example an epoxy adhesive, is deposited in the cavity 43 beneath said defective LED. The adhesive material typically extends from the central area of the defective LED up to the support face 400. The bonding force of the adhesive material is typically greater than the bonding force of the transfer device on the face 30₂ of the LED. Thus, during transfer of the LEDs, the defective LED remains advantageously attached to the support. It is not transferred onto the receiver substrate 2. This allows facilitating the repair at the receiver substrate, for example if this receiver substrate is directly a screen substrate intended to be integrated into the end product. Thus, the transfer structure may be advantageously modified locally to fasten a defective LED to the support, before transfer of the other LEDs. Advantageously, the cavity present beneath each of the LEDs may be used to achieve this fastening, typically by filling said cavity with an adhesive material. According to one possibility, fastening one or more LED(s) may be carried out without said LEDs being defective, for example so as to form a particular arrangement of the LEDs transferred onto the receiver substrate. The distribution of the LEDs over the receiver substrate is then different from the initial distribution of the LEDs over the support or the donor substrate. As illustrated throughout the preceding examples, the transfer structures and the transfer methods according to the invention therefore advantageously allow transferring optoelectronic devices from a donor substrate to a receiver substrate.

However, the invention is not limited to the previously-described embodiments.

In particular, the number, the shape and the arrangement of the projecting elements may be adapted according to the optoelectronic devices to be transferred.

1. A transfer structure comprising a support and an optoelectronic device attached to the support, the support comprising a base portion having a support face, and at least one element projecting from the support face, the optoelectronic device having a first face comprising a central area and a peripheral area surrounding the central area, wherein the at least one projecting element of the support is attached to the peripheral area of the first face of the optoelectronic device, so that the support face, the at least one projecting element and the first face of the device form a cavity under the central area.

2. The transfer structure according to claim 1, comprising at least two projecting elements, and preferably at least four projecting elements, evenly arranged on either side of the central area.

3. The transfer structure according to claim 1, wherein the at least one projecting element has a first dimension I₄₁ according to a first direction, a second dimension L₄₁ according to a second direction, and a third dimension h₄₁ according to a third direction, the first and second directions forming a base plane parallel to the support face, and the third direction being perpendicular to this base plane, such that at least one amongst the first and second dimensions I₄₁, L₄₁ is smaller than the third dimension h₄₁.

4. The transfer structure according to claim 1, wherein the optoelectronic device comprises at least one light-emitting diode in line with the central area, and has a second face opposite to the first face, said second face forming a light emission face.

5. The transfer structure according to claim 4, wherein the optoelectronic device further comprises an electrical interconnection portion forming the first face.

6. A transfer system comprising a plurality of transfer structures, according to claim 1, wherein at least one projecting element of two adjacent transfer structures is common to the peripheral areas of said adjacent transfer structures.

7. The transfer system according to claim 6, wherein the adjacent optoelectronic devices are separated from one another by trenches formed directly above the at least one projecting element.

8. The transfer system according to claim 7, wherein the at least one projecting element has a first dimension I₄₁ according to a first direction and a second dimension L₄₁ according to a second direction, the first and second directions forming a base plane parallel to the support face, and the trenches have at least one dimension 160 according to at least one amongst the first and second directions smaller than the first and second dimensions I₄₁, L₄₁ of the at least one projecting element.

9. The transfer system according to claim 8, wherein the trenches extend into the at least one projecting element according to a third direction perpendicular to the first and second directions.

10. A method for transferring a plurality of optoelectronic devices from a first substrate to a second substrate, said method comprising at least the following steps:
providing the first substrate carrying the optoelectronic devices, each of said optoelectronic devices having a first face on a side opposite to the first substrate, said first face comprising a central area and a peripheral area surrounding the central area,
forming a support for the optoelectronic devices, said support comprising a base portion having a support face, and at least one element projecting from the support face, each peripheral area being attached to said at least one projecting element, so that the support face, the at least one projecting element and the first face of the device form a cavity under the central area,
removing the first substrate,
detaching the optoelectronic devices from the support, and transferring them onto a second substrate, at their first faces.

11. The method according to claim 10, further comprising, after removal of the first substrate and before detachment of the optoelectronic devices, forming trenches separating the optoelectronic devices from one another, so that these are individualized and supported only by the at least one projecting element.

12. The method according to claim 11, wherein the trenches are formed by etching directly above the at least one projecting element, starting from a second face of the optoelectronic devices opposite to the first face.

13. The method according to claim 12, wherein etching is configured so that the trenches run partially in the at least one projecting element.

14. The method according to claim 10, wherein each of the optoelectronic devices comprises at least one light-emitting diode and an electrical interconnection portion, the at least one light-emitting diode being made on the first substrate and said electrical interconnection portion being made separately on a support layer, said electrical interconnection portion then being transferred by hybridization onto the at least one light-emitting diode, before forming the support.

15. The method according to claim 10, wherein the at least one projecting element is formed before being attached to the peripheral areas of the first faces of the optoelectronic devices.

16. The method according to claim 14, wherein the at least one projecting element is formed by etching said support layer, and is then attached on a planar substrate so as to form the support, before removing the first substrate.

17. The method according to claim 10, further comprising, before detaching the optoelectronic devices, fastening only part of the optoelectronic devices on the support face, said fastening being carried out by deposition of an adhesive material in the cavity, between the central area and the support face.

18. The method according to claim 17 further comprising, before fastening, an electrical test configured to detect defective optoelectronic devices, said fastening being carried out only for said defective optoelectronic devices.
